(19) United States
(12) Patent Application Publication
(10) Pub. No.: US 2022/0384560 A1
(43) Pub. Date: Dec. 1, 2022

(54) INDUCTORS IN TRENCHES WITHIN A SUBSTRATE

(71) Applicant: Intel Corporation, Santa Clara, CA (US)

(72) Inventor: Telesphor KAMGAING, Chandler, AZ (US)

(21) Appl. No.: 17/334,194

(22) Filed: May 28, 2021

(51) Int. Cl. H01L 49/02; H01F 5/00; H01F 5/06

(52) U.S. Cl. CPC H01L 28/10; H01F 5/003; H01F 5/06

(57) ABSTRACT

Embodiments described herein may be related to apparatuses, processes, and techniques related to inductors located within a substrate. An inductor may be created in a glass core using a laser-assisted etching of glass interconnects techniques to create trenches or vias within the glass substrate, into which conductive material may be plated or filled to create the inductor. In embodiments, the inductors may be low equivalent series resistance (ESR) compact air-core inductors. Other embodiments may be described and/or claimed.

### FIELD

Embodiments of the present disclosure generally relate to the field of semiconductor packaging, and in particular to inductors.

### BACKGROUND

Continued growth in virtual machines and cloud computing will continue to increase the demand for increased power to semiconductor packaging components.

### BRIEF DESCRIPTION OF THE DRAWINGS

FIG. 1 illustrates multiple examples of laser-assisted etching of glass interconnects processes, in accordance with embodiments.

FIG. 2 illustrates multiple views of an inductor in a single trench within a substrate, in accordance with embodiments.

FIG. 3 illustrates a legacy implementation of an inductor.

FIG. 4 illustrates multiple views of other inductors in a single trench within a substrate, in accordance with embodiments.

FIG. 5 illustrates multiple views of an inductor in multiple trenches within a substrate, in accordance with embodiments.

FIG. 6 illustrates an example process for creating an inductor in a single trench within a glass substrate, in accordance with embodiments.

FIG. 7 schematically illustrates a computing device, in accordance with embodiments.

### DETAILED DESCRIPTION

Embodiments described herein may be related to apparatuses, processes, and techniques related to inductors located within a substrate. In embodiments, the inductors may be created in a glass core using a laser-assisted etching of glass interconnects techniques, which may be referred to as “LEGIT” techniques, to create trenches or vias within the glass substrate into which conductive material may be placed to create the inductor. In embodiments, the inductors may be low equivalent series resistance (ESR) compact air-core inductors. In embodiments, the resistance of the inductance may be decreased by extending the trace thickness based on varying via or trench sizes or depths inside the glass core. In embodiments, the trace width may be narrow and limited to a minimum via diameter allowed by the LEGIT technique.

Embodiments described herein may be directed to in-package inductors with large trace thicknesses, narrow widths, and close spacing between individual turns. In embodiments, the inductors may include spirals formed in a glass core using the LEGIT technique using blind vias, which also may be referred to as trenches. Embodiments described herein may result in high inductance and low series resistance, facilitate a small inductor form factor which leads to smaller package sizes, and smaller traces spacing that leads to strong inductive coupling between neighboring turns and therefore leads to some mutual inductance. The resulting total inductance is the sum of the mutual inductance between the turns and the self-inductance of the turns. In embodiments, the inductors may provide efficient power delivery to electronic circuits, including CPUs and graphic cores. In addition, in embodiments, the inductors operate without additional magnetic material being added within or proximate to the inductor structure, and may operate just using traces that include copper or other conductive elements.

Inductors with low inductance values, for example <5 nH, and ESR in the order of few milli-Ohms may be needed for power delivery on die and on-package. Using legacy techniques, achieving a low series resistance and typical inductance value simultaneously is challenging. In legacy implementations, and order to circumvent the resistance challenge, magnetic materials have been introduced to enhance the self-inductance while keeping the length of the conductor (within the inductor) short. These legacy techniques help with the ESR reduction as the resistance is proportional to the length of the conductor. However, introducing magnetic material on die or on package is typically expensive and very complex. As a result, in legacy implementations magnetics are typically used when there are no alternative solutions. These legacy techniques may result in: large inductors that lead to package form factor increases, increased package layer accounts that lead to higher costs, and large devices that obstruct non-package signal routing.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

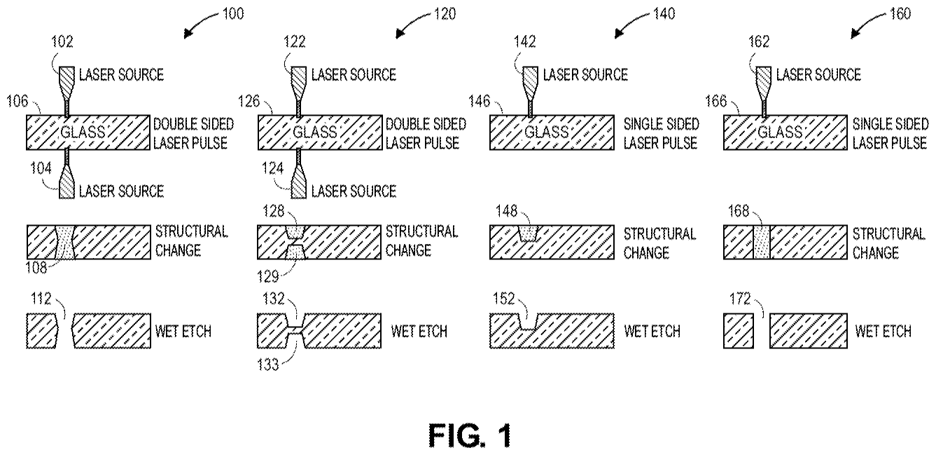

FIG. 1 illustrates multiple examples of laser-assisted etching of glass interconnects processes (which may be referred to as “LEGIT” herein), in accordance with embodiments. One use of the LEGIT technique is to provide an alternative substrate core material to the legacy copper clad laminate (CCL) core used in semiconductor packages used to implement products such as servers, graphics, clients, 5G, and the like. By using laser-assisted etching, crack free, high density via drills, hollow shapes may be formed into a glass substrate. In embodiments, different process parameters may be adjusted to achieve drills of various shapes and depths, thus opening the door for innovative devices, architectures, processes, and designs in glass. Embodiments, such as the bridge discussed herein, may also take advantage of these techniques.

Diagram 100 shows a high level process flow for a through and blind drill in a microelectronic package substrate (e.g. glass) using LEGIT to create a through via or a blind via. A through via 112 is created by laser pulses from two laser sources 102, 104 on opposite sides of a glass wafer 106. As used herein, a through drill and a through via refers to when the drill or the via starts on one side of the glass/substrate and ends on the other side. A blind drill and a blind via refers to when the drill or the via starts on the surface of the substrate and stops half way inside the substrate. In embodiments, the laser pulses from the two laser sources 102, 104 are applied perpendicularly to the glass wafer 106 to induce a morphological change 108, which may also be referred to as a structural change, in the glass that encounters the laser pulses. This morphological change 108 includes changes in the molecular structure of the glass to make it easier to etch out (remove a portion of the glass). In embodiments, a wet etch process may be used.

Diagram 120 shows a high level process flow for a double blind shape. A double blind shape 132, 133 may be created by laser pulses from two laser sources 122, 124, which may be similar to laser sources 102, 104, that are on opposite sides of the glass wafer 126, which may be similar to glass wafer 106. In this example, adjustments may be made in the laser pulse energy and/or the laser pulse exposure time from the two laser sources 122, 124. As a result, morphological changes 128, 129 in the glass 126 may result, with these changes making it easier to etch out portions of the glass. In embodiments, a wet etch process may be used.

Diagram 140 shows a high level process flow for a single-blind shape, which may also be referred to as a trench. In this example, a single laser source 142 delivers a laser pulse to the glass wafer 146 to create a morphological change 148 in the glass 146. As described above, these morphological changes make it easier to etch out a portion of the glass 152. In embodiments, a wet etch process may be used.

Diagram 160 shows a high level process flow for a through via shape. In this example, a single laser source 162 applies a laser pulse to the glass 166 to create a morphological change 168 in the glass 166, with the change making it easier to etch out a portion of the glass 172. As shown here, the laser pulse energy and/or laser pulse exposure time from the laser source 162 has been adjusted to create an etched out portion 172 that extends entirely through the glass 166.

With respect to FIG. 1, although embodiments show laser sources 102, 104, 122, 124, 142, 162 as perpendicular to a surface of the glass 106, 126, 146, 166, in embodiments, the laser sources may be positioned at an angle to the surface of the glass, with pulse energy and/or pulse exposure time variations in order to cause a diagonal via or a trench, or to shape the via, such as 112, 172, for example to make it cylindrical, tapered, or include some other feature. In addition, varying the glass type may also cause different features within a via or a trench as the etching of glass is strongly dependent on the chemical composition of the glass.

In embodiments using the process described with respect to FIG. 1, through hole vias 112, 172 may be created that are less than 10 μm in diameter, and may have an aspect ratio of 40:1 to 50:1. As a result, a far higher density of vias may be placed within the glass and be placed closer to each other at a fine pitch. In embodiments, this pitch may be 50 μm or less. After creating the vias or trenches, a metallization process may be applied in order to create a conductive pathway through the vias or trenches, for example a plated through hole (PTH). Using these techniques, finer pitch vias will result in better signaling, allowing more I/O signals to be put through the glass wafer and to other coupled components such as a substrate.

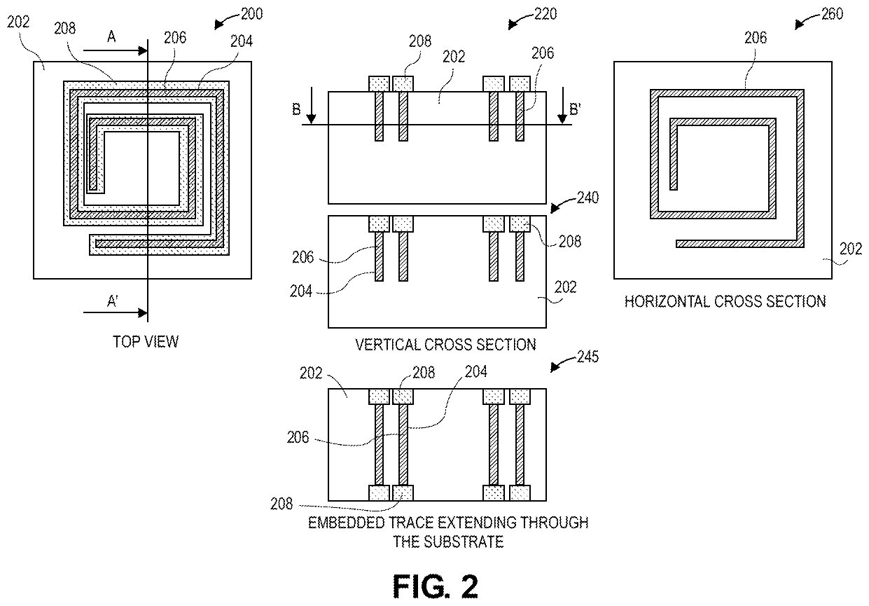

FIG. 2 illustrates multiple views of an inductor in a single trench within a substrate, in accordance with embodiments. Diagram 200 shows a top-down view of an inductor in a single trench, which may also be referred to as a single track spiral inductor. Substrate 202 is a substrate into which trenches 204 may be created. In embodiments, substrate 202 may be a glass substrate, a glass wafer, or a glass core. Substrate 202 in embodiments may be a silicon substrate, or a substrate manufactured out of some other material or a combination of materials.

Trench 204 may be created in the substrate 202 in a variety of patterns. Trench 204 may take the form of a spiral, or of some other form that may be used to implement an inductor in the substrate 202. If the substrate 202 is a glass substrate, the LEGIT technique as described above with respect to FIG. 1 may be used to create the trench 204, which may also be referred to as a blind via. In embodiments, if the glass substrate 202 has a 500 μm thickness, the trench 204 may have a minimum depth of 250 μm. As shown, the trench 204 may take the form of a two-turn spiral shape. In embodiments, the trench may have a diameter as small as 10 μm.

In embodiments, the trench 204 may be filled with a conductive material 206, such as copper or some other conductive metal or element. In embodiments, for trench widths less than 50 microns, the trench 204 may be fully filled with the conductive material 206. For larger width trenches, the conductive material 206 may be conformally plated within the trench 204. The conductive material 206, when placed in the trench 204, may also be referred to as a trace of the inductor. In embodiments, the conductive material 206 may extend partially into the substrate 202, as shown with respect to diagram 220 and 240, or the conductive material 206 may extend completely through the substrate 202 as shown in diagram 245.

As shown with respect to diagram 245, the LEGIT technique may be used to create a through via similar to trench 204 that extends completely through the substrate 202. Conductive material 206 may be subsequently added to either completely fill, partially fill, or be conformally plated to the sides of the trench 204. In embodiments, portions of the trench 204 may extend completely through the substrate 202, while other portions of the trench 204 extend only partially into the substrate 202.

In embodiments, a surface pad 208 may be electrically coupled with the conductive material 206. The surface pad 208 may be placed above a surface of the substrate 202 as shown in diagram 220. In embodiments, the surface pad 208 may be placed at or below a surface of the substrate 202 as shown in diagrams 240 and 245. In embodiments, an etching process, such as the LEGIT technique described in FIG. 1, may be used to create a recess into which the surface pad 208 may be inserted. In embodiments, the surface pad 208 may be the same width of the trench 204 and/or conductive material 206, or may be wider. In embodiments, the surface pad 208 may be placed proximate to all or part of the length of the trench 204 to allow electrical connectivity with other devices or power sources.

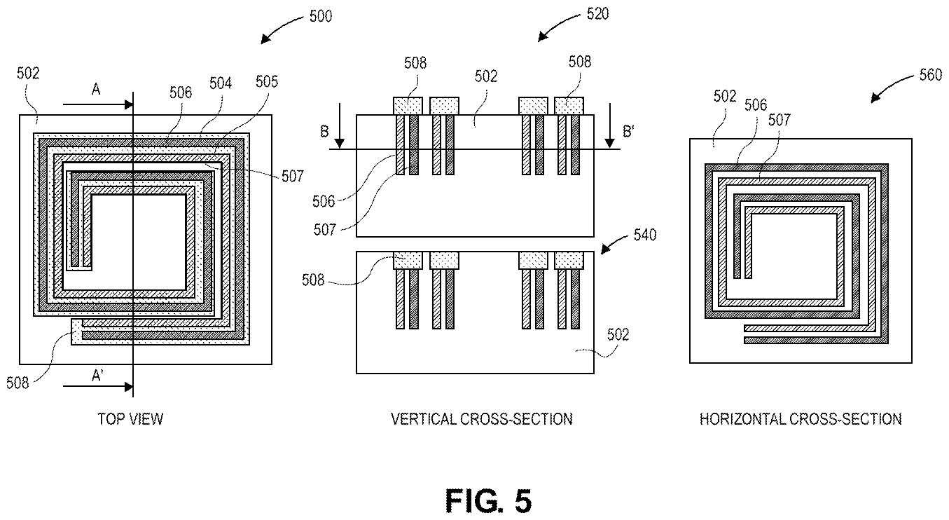

Diagram 260 shows a horizontal cross-section of the inductor 200. Note that the conductive material 206 forms a single track spiral within the substrate 202. The width of the conductive material 206, and the spacing between the spirals may be adjusted based on a number of operational factors. In one example, a conductive material 206 made of copper that is inserted within the class substrate 202 may have different coefficients of expansion (CTE). For example, the CT of copper is 16, where the CTE of glass varies from 0.6 to 9. This may affect how close the conductive material 206 may come to itself, as well as how deep the trench 204 may be etched. In embodiments, the different CTE may also affect the whether multiple trenches are used, as discussed further below with respect to FIG. 5.

In addition, the sides or the bottom of the conductive material 206 that extends into the substrate 202 may not be straight. For example, the sides of the bottom may be tapered. This may be due to different LEGIT techniques, as described above with respect to FIG. 1, used to etch the glass into which the conductive material 206 is placed.

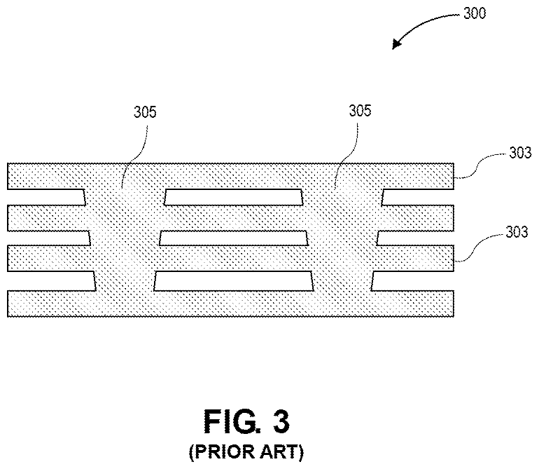

FIG. 3 illustrates a legacy implementation of an inductor. Diagram 300 shows a legacy implementation of an inductor created as part of a buildup layer or the core of a substrate. The legacy implementation includes one or more traces that are applied to layers 303 or core during the buildup process. In embodiments, one or more vias 305 may be subsequently created and filled with conductive material in order to cause the one or more layers 303 to be electrically coupled. In these legacy implementations, these inductors may be used for low-frequency applications like power delivery, but not for high-frequency applications. In legacy implementations, the layers may be 15 μm on the buildup, and 30 μm on the core.

Legacy inductors may have low mutual inductance between the turns, resulting in a large footprint. In addition, legacy inductors may obstruct other signals being routed inside the package. In addition, legacy inductors also come with increased package stack up because multiple layers have to be stacked to achieve low ESR.

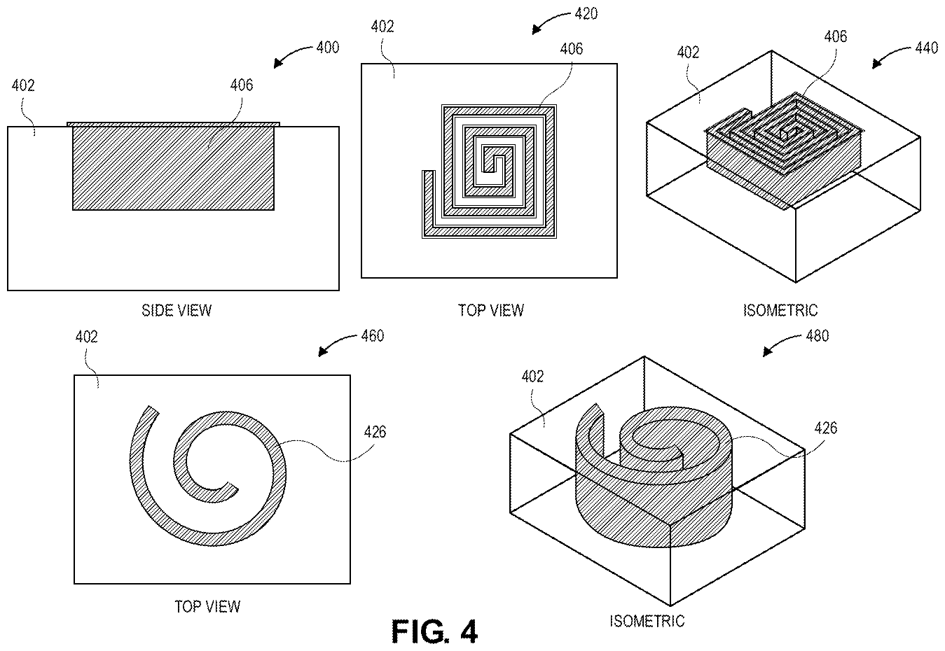

FIG. 4 illustrates multiple views of other inductors in a single trench within a substrate, in accordance with embodiments. Diagram 400 shows a side view of an inductor, which may be similar to inductor 200 of FIG. 2, that shows the conductive material 406, which may be similar to conductive material 206 of FIG. 2, that appears as a ribbon of conductive material 406, where the conductive material 406 extends partially into the glass substrate 402. Diagram 420 shows a top view of inductor 406, with the tighter spiral coil of the conductive material 406. Diagram 440 shows an isometric view of inductor 400, where the conductive material 406 extends partially into the glass substrate 402, which may be similar to glass substrate 202 of FIG. 2. Diagram 460 shows a top view of a different spiral pattern of conductive material 426, which may be similar to conductive material 406. Diagram 480 shows an isometric view of inductor 460.

FIG. 5 illustrates multiple views of an inductor in multiple trenches within a substrate, in accordance with embodiments. Diagram 500 shows an inductor that may be similar to diagram 200 of FIG. 2. The inductor 500 includes two trenches 504, 505 that are filled, respectively, with conductive material 506, 507. The resulting conductive material 506, 507 are formed parallel to each other and create a double spiral, as shown in horizontal cross-section 560. In other embodiments, there may be multiple trenches that are filled with conductive material to create multiple spirals, depending upon the requirements of the resulting inductor.

In embodiments, a multi-track spiral inductor utilizes narrow trenches when there is a large difference between the coefficient of thermal expansion of the conductive filling and the glass. For example, for a copper-filled trench in a glass with CTE of 0.6, the trench width may be between 5 and 20 μm. Many of those trenches can then be connected in parallel to reduce the ESR. If the CTE of glass is close to 9, the trench width may be 40 μm and thus it may not be necessary to connect several of those trenches in parallel.

As shown, the conductive material 506, 507 may be electrically coupled using a pad 508. In embodiments, the pad 508 may be disposed on top of the substrate 502, as shown in cross-section 520, or may be partially or completely recessed within the substrate 502 as shown in cross-section 540. The pad 508 may be continuous, or may be intermittent, causing electrical coupling between the conductive material 506, 507 at one or more points along the inductor 500. In other embodiments, one or more of the trenches 504, 505 may be vias that extend completely through the substrate 502. In these embodiments, another pad, which may be similar to pad 508, may be placed on the opposite side of the substrate 502 to electrically couple the conductive material of the inductor 500.

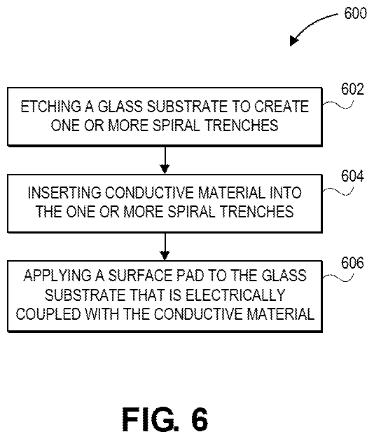

FIG. 6 illustrates an example process for creating an inductor in a single trench within a glass substrate, in accordance with embodiments. Process 600 may be implemented using one or more processes, apparatus, systems, and/or techniques described herein with respect to FIGS. 1-2 and 4-5.

At block 602, the process includes etching a glass substrate to create one or more spiral trenches. In embodiments, the glass substrate may be similar to glass substrate 106, 126, 146, 166 of FIG. 1, glass substrate 202 of FIG. 2, glass substrate 402 of FIG. 4, or glass substrate 502 of FIG. 5. In embodiments, the etching process may involve techniques as described with respect to FIG. 1. These techniques include using a laser source, such as laser source 102, 104, 122, 124, 142, 162 of FIG. 1 to cause a structural change within the glass substrate by varying the timing and/or energy of the laser pulse emanating from the laser source into the glass substrate to alter the structure of the glass in a portion of the glass substrate. In embodiments, the glass substrate may subsequently be submitted to an etching process, which may include a wet etching process, to remove the glass with the altered structure from the glass substrate. As a result of the etching process, a trench and/or via may be formed within the glass substrate.

At block 604, the process may further include inserting conductive material into the one or more spiral trenches. In embodiments, the spiral trenches may be similar to trenches 204 of FIG. 2, or 504 of FIG. 5. In embodiments, the conductive material may include a copper or other similar conductive material. In embodiments, the conductive material may be plated on the edges and/or bottom of the trenches, or may be plated on the edges of a via that extends from one side of the glass substrate to the other side of the glass substrate. In embodiments, the conductive material may fill the trench or the via completely.

At block 606, the process may further include applying a surface pad to the glass substrate that is electrically coupled with the conductive material. In embodiments, the surface pad may be similar to pads 208 of FIG. 2, or pads 508 of FIG. 5. In embodiments, the surface pads may be placed directly on top of the glass substrate and electrically coupled with the conductive material. In other embodiments, the surface pads may be placed within an etched trench to cause the top of the pad to be flush with the surface of the glass substrate.

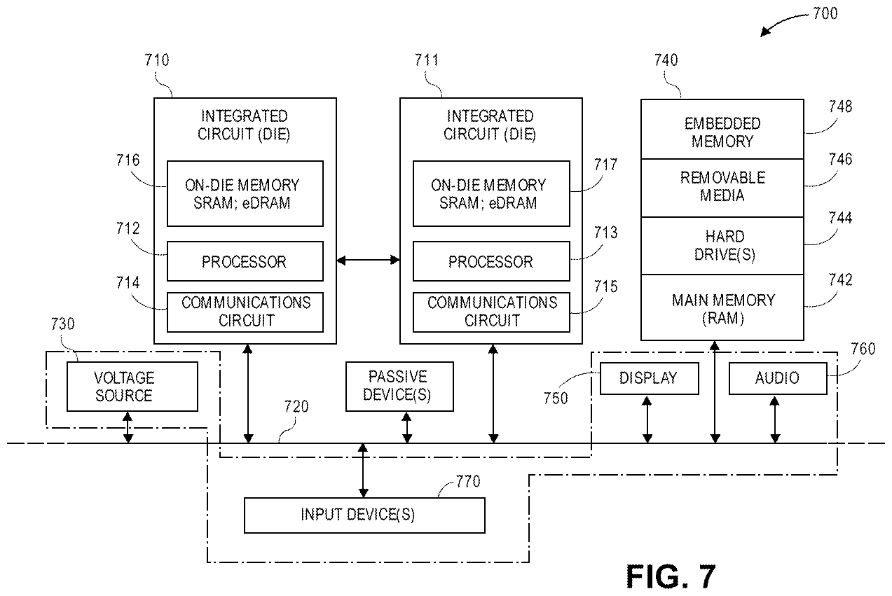

FIG. 7 schematically illustrates a computing device, in accordance with embodiments. The computer system 700 (also referred to as the electronic system 700) as depicted can embody all or part of inductors in trenches within a substrate, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, all or part of inductors in trenches within a substrate, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including all or part of inductors in trenches within a substrate, according to any of the several disclosed embodiments and their equivalents, an electronic system, a computer system, one or more methods of fabricating an integrated circuit, and one or more methods of fabricating an electronic assembly that includes a package substrate implementing all or part of inductors in trenches within a substrate, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed processes used for inductors in trenches within a substrate embodiments and their equivalents. A foundation substrate may be included, as represented by the dashed line of FIG. 7. Passive devices may also be included, as is also depicted in FIG. 7.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

### EXAMPLES

The following paragraphs describe examples of various embodiments.

Example 1 is an inductor comprising: a substrate having a first side and a second side opposite the first side; a trench extending from the first side of the substrate toward the second side of the substrate; wherein the trench includes an electrically conductive material that extends from the first side of the substrate to a depth of the trench; and wherein a length of the trench forms an overlapping spiral in the substrate.

Example 2 includes the inductor of example 1, wherein the trench is substantially perpendicular to the first side of the substrate.

Example 3 includes the inductor of example 1, wherein the substrate is a glass panel, glass wafer, or glass substrate.

Example 4 includes the inductor of example 1, wherein a width of the trench is 10 μm or the depth of the trench is at least 250 μm.

Example 5 includes the inductor of example 1, wherein the electrically conductive material is fully filled within the trench.

Example 6 includes the inductor of example 1, wherein the electrically conductive material is plated on a side of the trench.

Example 7 includes the inductor of example 1, further comprising traces electrically and physically coupled with the electrically conductive material at the first side of the substrate.

Example 8 includes the inductor of example 7, wherein the traces extend above the first side of the substrate.

Example 9 includes the inductor of example 1, wherein the trench extends from the first side of the substrate to the second side of the substrate.

Example 10 includes the inductor of example 9, further comprising traces that are electrically and physically coupled with the electrically conductive material at the second side of the substrate.

Example 11 includes an inductor, comprising: a substrate having a first side and a second side opposite the first side; a plurality of trenches extending from the first side of the substrate toward the second side of the substrate, the plurality of trenches being substantially parallel; wherein the plurality of trenches include an electrically conductive material that extends from the first side of the substrate to a depth, respectively, of the plurality of trenches; and wherein the plurality of trenches form an overlapping spiral in the substrate.

Example 12 includes the inductor of example 11, further comprising traces electrically and physically coupled with the electrically conductive material at the first side of the substrate.

Example 13 includes the inductor of example 11, wherein the substrate is a glass panel, glass wafer, or glass substrate.

Example 14 includes the inductor of example 11, wherein a width of the trench is 10 μm or the depth of the trench is at least 250 μm.

Example 15 includes the inductor of example 11, wherein at least one of the plurality of trenches extend from the first side of the substrate to the second side of the substrate.

Example 16 includes the inductor of example 11, further comprising traces that electrically and physically couple with the electrically conductive material in the plurality of trenches at the second side of the substrate.

Example 17 is a system, comprising: a device; an inductor electrically coupled with the device to provide power to the device, the inductor comprising: a glass substrate having a first side and a second side opposite the first side; a trench extending from the first side of the glass substrate toward the second side of the glass substrate; wherein the trench includes an electrically conductive material that extends from the first side of the glass substrate to a depth of the trench; and wherein the trench forms an overlapping spiral in the glass substrate.

Example 18 includes the system of example 17, wherein the electrically conductive material is a selected one of fully filled within the trench plated on a side of the trench.

Example 19 includes the system of example 17, further comprising traces electrically and physically coupled with the electrically conductive material at the first side of the substrate.

Example 20 includes the system of example 17, wherein the trench extends from the first side of the glass substrate to the second side of the glass substrate, and further comprising traces that are electrically and physically coupled with the electrically conductive material at the second side of the glass substrate.

What is claimed is:

1. An inductor comprising:
a substrate having a first side and a second side opposite the first side;
a trench extending from the first side of the substrate toward the second side of the substrate;
wherein the trench includes an electrically conductive material that extends from the first side of the substrate to a depth of the trench; and
wherein a length of the trench forms an overlapping spiral in the substrate.

2. The inductor of claim 1, wherein the trench is substantially perpendicular to the first side of the substrate.

3. The inductor of claim 1, wherein the substrate is a glass substrate.

4. The inductor of claim 1, wherein a width of the trench is 10 μm or the depth of the trench is at least 250 μm.

5. The inductor of claim 1, wherein the electrically conductive material is fully filled within the trench.

6. The inductor of claim 1, wherein the electrically conductive material is plated on a side of the trench.

7. The inductor of claim 1, further comprising traces electrically and physically coupled with the electrically conductive material at the first side of the substrate.

8. The inductor of claim 7, wherein the traces extend above the first side of the substrate.

9. The inductor of claim 1, wherein the trench extends from the first side of the substrate to the second side of the substrate.

10. The inductor of claim 9, further comprising traces that are electrically and physically coupled with the electrically conductive material at the second side of the substrate.

11. An inductor, comprising:
a substrate having a first side and a second side opposite the first side;
a plurality of trenches extending from the first side of the substrate toward the second side of the substrate, the plurality of trenches being substantially parallel;
wherein the plurality of trenches include an electrically conductive material that extends from the first side of the substrate to a depth, respectively, of the plurality of trenches; and
wherein the plurality of trenches form an overlapping spiral in the substrate.

12. The inductor of claim 11, further comprising traces electrically and physically coupled with the electrically conductive material at the first side of the substrate.

13. The inductor of claim 11, wherein the substrate is a glass substrate.

14. The inductor of claim 11, wherein a width of the trench is 10 μm or the depth of the trench is at least 250 μm.

15. The inductor of claim 11, wherein at least one of the plurality of trenches extend from the first side of the substrate to the second side of the substrate.

16. The inductor of claim 11, further comprising traces that electrically and physically couple with the electrically conductive material in the plurality of trenches at the second side of the substrate.

17. A system, comprising:
a device;
an inductor electrically coupled with the device to provide power to the device, the inductor comprising:
a glass substrate having a first side and a second side opposite the first side;
a trench extending from the first side of the glass substrate toward the second side of the glass substrate;
wherein the trench includes an electrically conductive material that extends from the first side of the glass substrate to a depth of the trench; and
wherein the trench forms an overlapping spiral in the glass substrate.

18. The system of claim 17, wherein the electrically conductive material is a selected one of fully filled within the trench plated on a side of the trench.

19. The system of claim 17, further comprising traces electrically and physically coupled with the electrically conductive material at the first side of the substrate.

20. The system of claim 17, wherein the trench extends from the first side of the glass substrate to the second side of the glass substrate, and further comprising traces that are electrically and physically coupled with the electrically conductive material at the second side of the glass substrate.
